(19) United States
(12) Patent Application Publication
(10) Pub. No.: US 2022/0141403 A1
(43) Pub. Date: May 5, 2022

(54) INTENSITY AND CONTRAST CHANGE DETECTION CAPABLE PIXELS WITH SHARED PHOTODETECTOR

(71) Applicant: APPLE INC., Cupertino, CA (US)

(72) Inventors: Emanuele MANDELLI, Mountain View, CA (US); Andrew K. McMAHON, San Carlos, CA (US); Nikolai E. BOCK, San Jose, CA (US)

(21) Appl. No.: 17/578,601

(22) Filed: Jan. 19, 2022

Related U.S. Application Data
(63) Continuation of application No. PCT/US2020/042267, filed on Jul. 16, 2020.
(60) Provisional application No. 62/878,860, filed on Jul. 26, 2019.
(60) Provisional application No. 62/959,269, filed on Jan. 10, 2020.

(51) Int. Cl. H04N 5/353; H04N 5/347; H04N 5/369

(52) U.S. Cl. CPC H04N 5/353; H01L 27/14665; H04N 5/3698; H04N 5/347

(57) ABSTRACT

Various implementations disclosed herein include devices, systems, and methods implemented by an electronic device with an imaging sensor including a plurality of pixels (e.g., a matrix of pixels) that each are capable of detecting illumination intensity or contrast change using at least one shared photosensor. In some implementations, the imaging sensor is capable of operating in a first illumination intensity detecting mode (e.g., in a frame-based camera mode) or in a second contrast change detecting mode (e.g., in an event camera mode). In some implementations, the first illumination intensity detecting mode and the second contrast change detecting mode are mutually exclusive. In some implementations, pixels at an imaging sensor include two transfer transistors (e.g., gates) where a first transfer transistor allows intensity detection, and a second transfer transistor allows contrast change detection.

### TECHNICAL FIELD

The present disclosure generally relates to systems, methods, and devices that detect illumination intensity and contrast change.

### SUMMARY

Various implementations disclosed herein include devices, systems, and methods implemented by an electronic device with an imaging sensor including a plurality of pixels (e.g., a matrix of pixels) that each are capable of detecting illumination intensity or contrast change using a shared photodetector(s). In some implementations, the imaging sensor is capable of operating in a first illumination intensity detecting mode (e.g., in a frame-based camera mode) or in a second contrast change detecting mode (e.g., in an event camera/dynamic vision sensor (DVS) mode). In some implementations, the first illumination intensity detecting mode and the second contrast change detecting mode are mutually exclusive, for example, where each pixel operates in only one of the modes at a given point in time. In some implementations, pixels of an imaging sensor include two transfer transistors (e.g., gates) where a first transfer transistor allows intensity detection, and a second transfer transistor allows contrast change detection. In some implementations, the first transfer transistor of the two transfer transistors enables full charge transfer and photodiode depletion during intensity detection for the pixels of the imaging sensor. In some implementations when using the first transfer gate, pixels at the imaging sensor can operate using a standard configuration such as a four transistor (4T) pixel. In some implementations, the second transfer transistor of the two transfer transistors enables photoelectrons to flow through for contrast change detection. In some implementations, the two transfer transistors enable mutually exclusive operational modes to be performed by the imaging sensor.

### BRIEF DESCRIPTION OF THE DRAWINGS

So that the present disclosure can be understood by those of ordinary skill in the art, a more detailed description may be had by reference to aspects of some illustrative implementations, some of which are shown in the accompanying drawings.

FIG. 1 is a block diagram of an example system in accordance with some implementations.

FIG. 2 is a block diagram of an example controller, in accordance with some implementations.

FIG. 3 is a block diagram of an example electronic device, in accordance with some implementations.

FIG. 4 is a block diagram of an example pixel for an imaging sensor in accordance with some implementations.

FIGS. 5-10 are schematic diagrams of additional example pixels for an imaging sensor in accordance with some implementations.

FIG. 11 is a diagram of an example contrast charge detection circuit with binning in accordance with some implementations.

FIG. 12 is a block diagram of pixel sensors for an event camera and an example circuit diagram of a pixel sensor, in accordance with some implementations.

FIG. 13 is a diagram of an example arrangement of a 4 transistor (4T) pixel.

In accordance with common practice the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DESCRIPTION

Numerous details are described in order to provide a thorough understanding of the example implementations shown in the drawings. However, the drawings merely show some example aspects of the present disclosure and are therefore not to be considered limiting. Those of ordinary skill in the art will appreciate that other effective aspects or variants do not include all of the specific details described herein. Moreover, well-known systems, methods, components, devices and circuits have not been described in exhaustive detail so as not to obscure more pertinent aspects of the example implementations described herein.

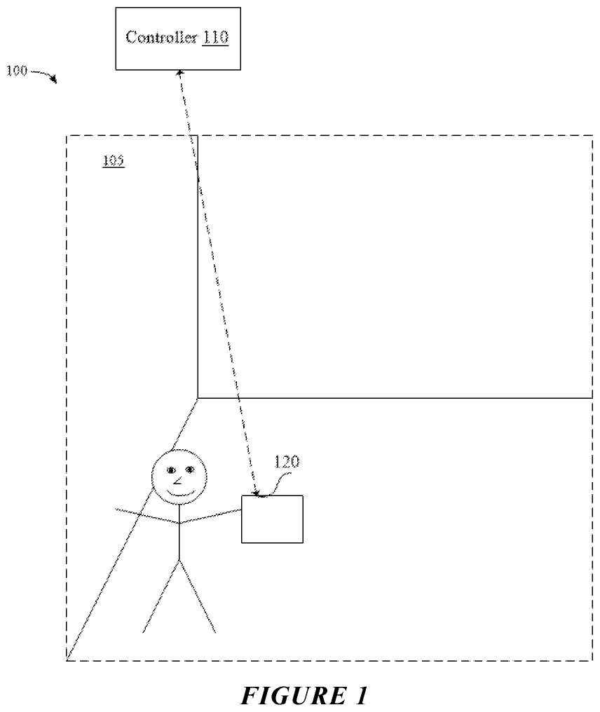

FIG. 1 is a block diagram of an example operating environment 100 in accordance with some implementations. As a non-limiting example, the operating environment 100 includes a controller 110 and an electronic device (e.g., a laptop) 120, one or all of which may be in a physical setting 105.

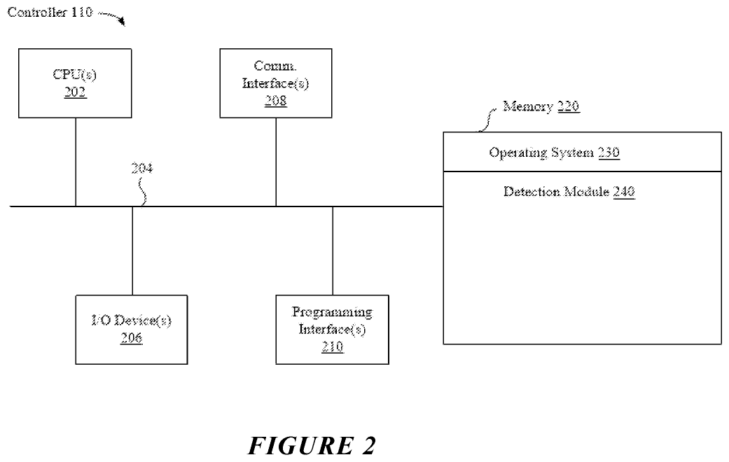

In some implementations, the controller 110 may be configured to detect intensity and contrast change. In some implementations, the controller 110 includes a suitable combination of software, firmware, or hardware. The controller 110 is described in greater detail below with respect to FIG. 2. In some implementations, the controller 110 is a computing device that is local or remote relative to the physical setting 105.

In one example, the controller 110 is a local server located within the physical setting 105. In another example, the controller 110 is a remote server located outside of the physical environment 105 (e.g., a cloud server, central server, etc.). In some implementations, the controller 110 is communicatively coupled with a corresponding electronic device 120 via one or more wired or wireless communication channels 144 (e.g., BLUETOOTH, IEEE 802.11x, IEEE 802.16x, IEEE 802.3x, etc.).

In some implementations, the controller 110 and a corresponding electronic device (e.g., 120) are configured to detect intensity and contrast change together.

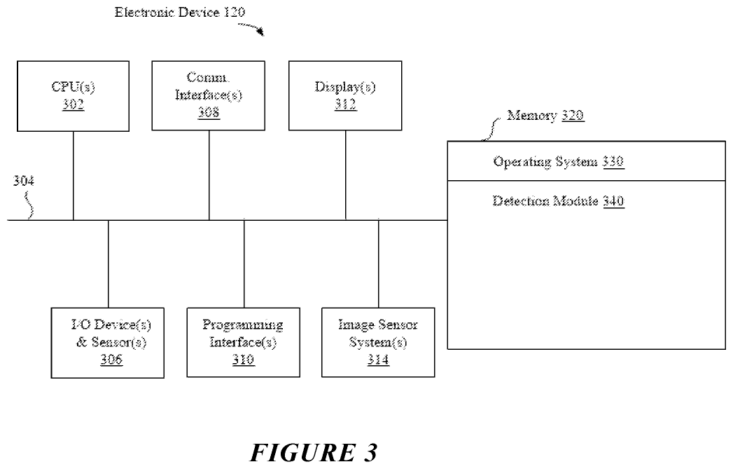

In some implementations, the electronic device 120 is configured to detect intensity and contrast change. In some implementations, the electronic device 120 includes a suitable combination of software, firmware, or hardware. The electronic device 120 is described in greater detail below with respect to FIG. 3. In some implementations, the functionalities of the corresponding controller 110 is provided by or combined with the electronic device 120, for example, in the case of an electronic device that functions as a stand-alone unit.

FIG. 2 is a block diagram of an example of a controller 110 in accordance with some implementations. While certain specific features are illustrated, those skilled in the art will appreciate from the present disclosure that various other features have not been illustrated for the sake of brevity, and so as not to obscure more pertinent aspects of the implementations disclosed herein. To that end, as a non-limiting example, in some implementations the controller 110 includes one or more processing units 202 (e.g., microprocessors, application-specific integrated-circuits (ASICs), field-programmable gate arrays (FPGAs), graphics processing units (GPUs), central processing units (CPUs), processing cores, or the like), one or more input/output (I/O) devices 206, one or more communication interfaces 208 (e.g., universal serial bus (USB), FIREWIRE, THUNDERBOLT, IEEE 802.3x, IEEE 802.11x, IEEE 802.16x, global system for mobile communications (GSM), code division multiple access (CDMA), time division multiple access (TDMA), global positioning system (GPS), infrared (IR), BLUETOOTH, ZIGBEE, or the like type interface), one or more programming (e.g., I/O) interfaces 210, a memory 220, and one or more communication buses 204 for interconnecting these and various other components.

In some implementations, the one or more communication buses 204 include circuitry that interconnects and controls communications between system components. In some implementations, the one or more I/O devices 206 include at least one of a keyboard, a mouse, a touchpad, a joystick, one or more microphones, one or more speakers, one or more image capture devices or other sensors, one or more displays, or the like.

The memory 220 includes high-speed random-access memory, such as dynamic random-access memory (DRAM), static random-access memory (CGRAM), double-data-rate random-access memory (DDR RAM), or other random-access solid-state memory devices. In some implementations, the memory 220 includes non-volatile memory, such as one or more magnetic disk storage devices, optical disk storage devices, flash memory devices, or other non-volatile solid-state storage devices. The memory 220 optionally includes one or more storage devices remotely located from the one or more processing units 202. The memory 220 comprises a non-transitory computer readable storage medium. In some implementations, the memory 220 or the non-transitory computer readable storage medium of the memory 220 stores the following programs, modules and data structures, or a subset thereof including an optional operating system 230 and detection module 240.

The operating system 230 includes procedures for handling various basic system services and for performing hardware dependent tasks. In some implementations, the detection module 240 is configured to detect intensity and contrast change. Moreover, FIG. 2 is intended more as functional description of the various features which are present in a particular implementation as opposed to a structural schematic of the implementations described herein. As recognized by those of ordinary skill in the art, items shown separately could be combined and some items could be separated. For example, some functional modules shown separately in FIG. 2 could be implemented in a single module and the various functions of single functional blocks could be implemented by one or more functional blocks in various implementations. The actual number of modules and the division of particular functions and how features are allocated among them will vary from one implementation to another and, in some implementations, depends in part on the particular combination of hardware, software, or firmware chosen for a particular implementation.

FIG. 3 is a block diagram of an example of an electronic device 120 in accordance with some implementations. While certain specific features are illustrated, those skilled in the art will appreciate from the present disclosure that various other features have not been illustrated for the sake of brevity, and so as not to obscure more pertinent aspects of the implementations disclosed herein. To that end, as a non-limiting example, in some implementations the electronic device 120 includes one or more processing units 302 (e.g., microprocessors, ASICs, FPGAs, GPUs, CPUs, processing cores, or the like), one or more input/output (I/O) devices and sensors 306, one or more communication interfaces 308 (e.g., USB, FIREWIRE, THUNDERBOLT, IEEE 802.3x, IEEE 802.11x, IEEE 802.16x, GSM, CDMA, TDMA, GPS, IR, BLUETOOTH, ZIGBEE, SPI, I2C, or the like type interface), one or more programming (e.g., I/O) interfaces 310, one or more displays 312, one or more interior or exterior facing image sensor systems 314, a memory 320, and one or more communication buses 304 for interconnecting these and various other components.

In some implementations, the one or more communication buses 304 include circuitry that interconnects and controls communications between system components. In some implementations, the one or more I/O devices and sensors 306 include at least one of an inertial measurement unit (IMU), an accelerometer, a magnetometer, a gyroscope, a thermometer, one or more physiological sensors (e.g., blood pressure monitor, heart rate monitor, blood oxygen sensor, blood glucose sensor, etc.), one or more microphones, one or more speakers, a haptics engine, one or more depth sensors (e.g., a structured light, a time-of-flight, or the like), or the like.

In some implementations, the one or more displays 312 are configured to present content to the user. In some implementations, the one or more displays 312 correspond to holographic, digital light processing (DLP), liquid-crystal display (LCD), liquid-crystal on silicon (LCoS), organic light-emitting field-effect transitory (OLET), organic light-emitting diode (OLED), surface-conduction electron-emitter display (SED), field-emission display (FED), quantum-dot light-emitting diode (QD-LED), micro-electromechanical system (MEMS), or the like display types. In some implementations, the one or more displays 312 correspond to diffractive, reflective, polarized, holographic, etc. waveguide displays. For example, the electronic device may include a single display. In another example, the electronic device may include a display for each eye of the user.

The memory 320 includes high-speed random-access memory, such as DRAM, CGRAM, DDR RAM, or other random-access solid-state memory devices. In some implementations, the memory 320 includes non-volatile memory, such as one or more magnetic disk storage devices, optical disk storage devices, flash memory devices, or other non-volatile solid-state storage devices. The memory 320 optionally includes one or more storage devices remotely located from the one or more processing units 302. The memory 320 comprises a non-transitory computer readable storage medium. In some implementations, the memory 320 or the non-transitory computer readable storage medium of the memory 320 stores the following programs, modules and data structures, or a subset thereof including an optional operating system 330 and a detection module 340.

The operating system 330 includes procedures for handling various basic system services and for performing hardware dependent tasks. In some implementations, the detection module 340 is configured to detect intensity and contrast change. Moreover, FIG. 3 is intended more as a functional description of the various features which are present in a particular implementation as opposed to a structural schematic of the implementations described herein. As recognized by those of ordinary skill in the art, items shown separately could be combined and some items could be separated. For example, some functional modules shown separately in FIG. 3 could be implemented in a single module and the various functions of single functional blocks could be implemented by one or more functional blocks in various implementations. The actual number of modules and the division of particular functions and how features are allocated among them will vary from one implementation to another and, in some implementations, depends in part on the particular combination of hardware, software, or firmware chosen for a particular implementation.

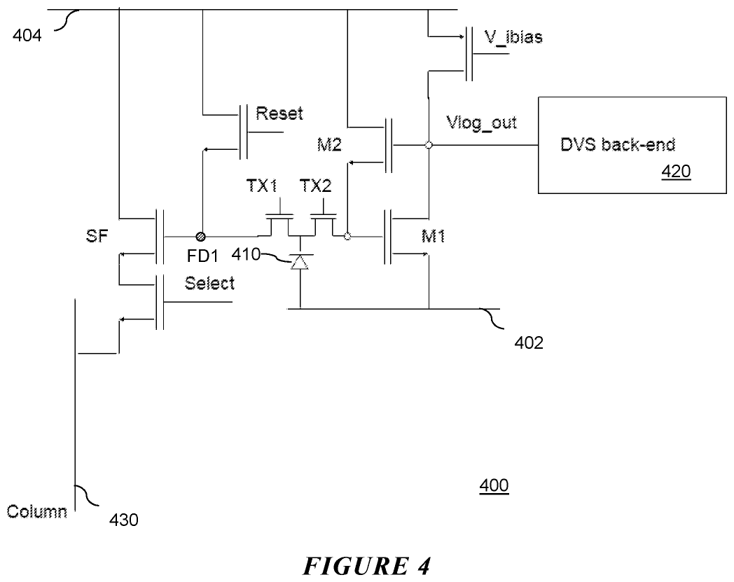

FIG. 4 is a block diagram of an example pixel for an imaging sensor that is capable of detecting illumination intensity or contrast change using a shared photodetector (e.g., a single photodetector) in accordance with some implementations. As shown in FIG. 4, a hybrid pixel 400 uses a single photosensor to operate in a first mode (e.g., illumination intensity detection, frame camera) and to operate in a second mode (e.g., contrast change detection, event camera). In some implementations, the hybrid pixel 400 uses a first conductive readout path in the first mode. In some implementations, the hybrid pixel 400 uses a second conductive readout path in the second mode.

As shown in FIG. 4, the hybrid pixel 400 includes a single photodetector 410 that is coupled between a first reference voltage (e.g., ground) and the first conductive readout path (e.g., illumination intensity) to output 430 through a first readout transistor TX1. The photodetector 410 is also connected between the first reference voltage and a second conductive readout path (e.g., photocurrent) to a dynamic vision sensor (DVS) back-end 420 through the second readout transistor TX2. In some implementations, the first conductive readout path is a four transistor (4T) pixel circuit including the first readout transistor TX1, a reset transistor (Reset), a source follower transistor (SF), a row select transistor (Select) to the output 430 (Column bus). In some implementations, the second conductive path includes the second readout transistor TX2, a transistor M1, a transistor M2 and a bias transistor (V_ibias) connected to the dynamic vision sensor (DVS) back-end.

As shown in FIG. 4, the first conductive path includes the reset transistor (Reset) with a second electrode (e.g., drain) connected to a second reference voltage 404 (e.g., Vcc), a first electrode (e.g., source) connected to a second electrode of the first readout transistor TX1, and a gate (e.g., third electrode/terminal) coupled to a reset control signal. The source follower transistor (SF) has a second electrode connected to the second reference voltage, a gate connected to the second electrode of the first readout transistor TX1 and the first electrode of the reset transistor (Reset), and a first electrode connected to a second electrode of the select transistor (Select). In some implementations, a floating diffusion node (FD1) is formed at the connection of the gate of the source follower transistor (SF), the second electrode of the first readout transistor TX1, and the first electrode of the reset transistor (Reset). The row select transistor (Select) has a first electrode connected to a column bus that is the output node 430.

In some implementations, operations of the hybrid pixel 400 in the first mode in a 2D array of photo-sensitive pixels 400 produces a frame or an image. In some implementations, operations of the first conductive path of the hybrid pixel 400 in a 2D array of photo-sensitive pixels 400 produces a frame or an image.

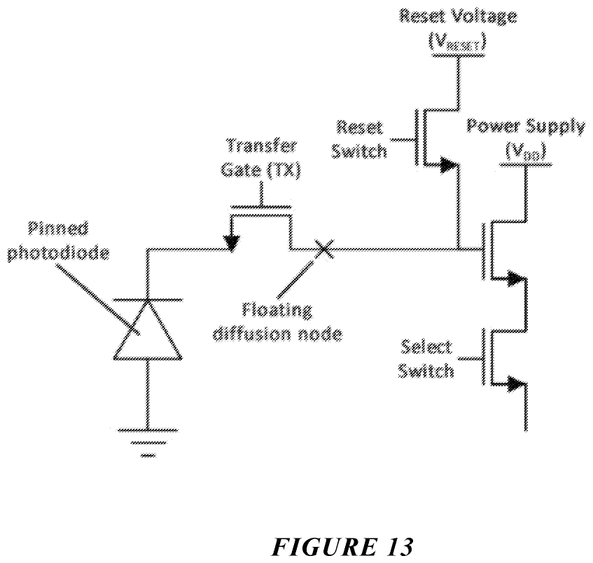

In some implementations, operations of the first conductive path of the hybrid pixel 400 include correlated double sampling (CDS) to reduce fixed pattern noise or kTC noise. In some implementations, operations of the first conductive path of the hybrid pixel 400 are described with respect to FIG. 13. In some implementations, the hybrid pixel 400 is at least a part of an image sensor including a 2D array of photo-sensitive pixels that, when the data from them is acquired and processed, produces a frame or an image. In some implementations, the photodetector 410 is a photodiode, photosensor, or the like.

In some implementations, the second conductive path of the hybrid pixel 400 detects events in the photocurrent generated by the photodetector 410.

As shown in FIG. 4, the second connective readout path includes the second readout transistor TX2 with a first electrode connected to the cathode of the photodetector 410 and a second electrode connected to a gate of the transistor M1. A first electrode of the transistor M1 is coupled to a first reference voltage 402 (e.g., ground voltage) and a second electrode is coupled to an input of the DVS back-end 420, a second electrode of the bias transistor (V_ibias), and a gate of the transistor M2. A second electrode of the transistor M2 is connected to the second reference voltage 404, and a first electrode of the transistor M2 is connected to the second electrode of the second readout transistor TX2, and the gate of the transistor M1. The bias transistor (V_ibias) has a first electrode connected to the second reference voltage 404 and a gate coupled to a bias control signal.

In a second mode of operations (e.g., contrast change detection, dynamic vision sensor, event camera), the hybrid pixel 400 enables the readout transistor TX2 so that the photocurrent from the photodetector 410 biases the transistor M2 and closes a loop with the transistor M1 to form a logarithmic front-end amplifier that provides an input to the DVS back-end 420. In some implementations, the connected transistors M1 and M2 generate a logarithmic relationship between the photocurrent from the photodetector 410 and the input signal (Vlog out) to the DVS back-end 420. In some implementations, the readout transistor TX2 is always enabled in the second mode.

As shown in FIG. 4, a total photocurrent transfer to the transistor M2 from the photodetector 410 through the enabled transistor TX2 is dependent on operations of the transistor M1 in the second mode of the pixel 400. In some implementations, there is a prescribed gate voltage (Vgs) to bias the transistor M1. In some implementations, the prescribed gate voltage (Vgs) to bias the transistor M1 is a small voltage depending on the technology used to implement the hybrid pixel 400. For example, the voltage to bias the transistor M1 is 300 mV, 400 mV, 500 mV or the like.

In some implementations, the gate voltage of the transistor M1 in the second mode of the pixel 400 is a higher voltage than a ground voltage. In some implementations, the gate voltage of the transistor M1 is higher than a pinning voltage (Vpn) of the photodetector 410 in the second mode of the pixel 400. In some implementations, the readout transistor TX2 operates as a switch so that all or a majority of the photocurrent from the photodetector 410 flows through the transistor M2 in the second mode of the pixel 400.

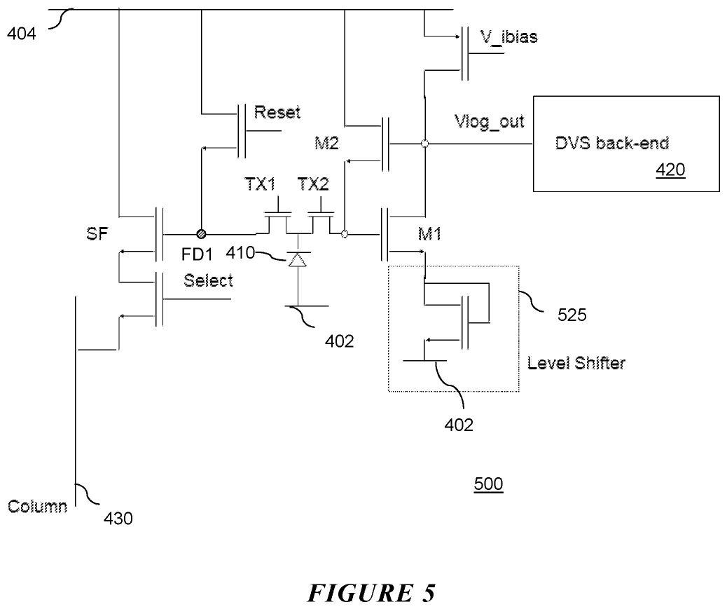

FIG. 5 is a block diagram of another example pixel for an imaging sensor that is capable of detecting illumination intensity or contrast change using shared photodetectors in accordance with some implementations. As shown in FIG. 5, the photodiode 410 is connected through a first conductive readout path (e.g., 4T pixel) to an output column or the output 430 in the first mode of operation of a hybrid pixel 500 as described with respect to FIG. 4. As shown in FIG. 5, a level shifter circuit is coupled in a second conductive path of the hybrid pixel 500. As shown in FIG. 5, a level shifter circuit 525 is coupled to the first electrode of the transistor M1. As shown in FIG. 5, the level shifter circuit 525 increases the gate voltage of the transistor M1. In some implementations, the level shifter circuit 525 increases the gate voltage of the transistor M1 relative to the photodetector 410 of the hybrid pixel 500. In some implementations, the level shifter circuit 525 includes a transistor having a first electrode connected to the first reference voltage 402 (e.g., ground voltage), a second electrode and a gate connected to the first electrode of the transistor M1.

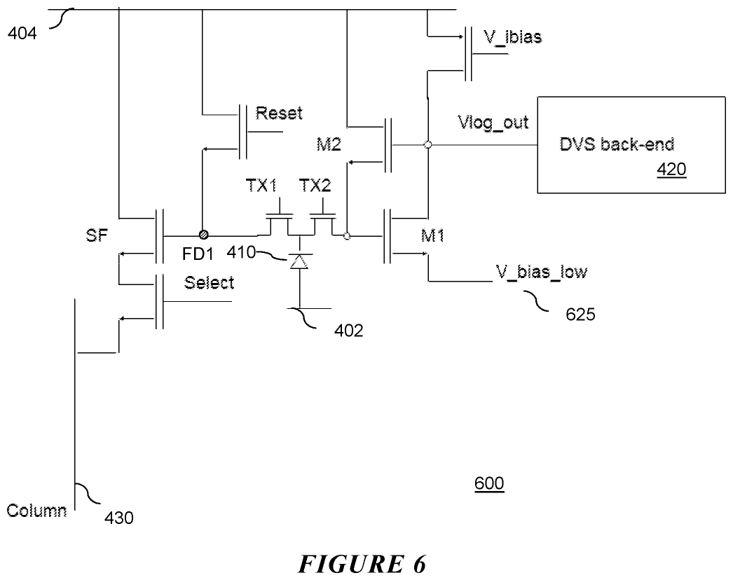

FIG. 6 is a block diagram of yet another example pixel for an imaging sensor that is capable of detecting illumination intensity or contrast change using shared photodetectors in accordance with some implementations. As shown in FIG. 6, the photodiode 410 is connected through a first conductive readout path (e.g., 4T pixel) to an output column or the output 430 in the first mode of operation of a hybrid pixel 600 as described with respect to FIG. 4. As shown in FIG. 6, an additional reference voltage is coupled in a second conductive path of the hybrid pixel 600. As shown in FIG. 6, a reference voltage 625 (e.g., low bias voltage), which is different from the first reference voltage 402 (e.g., ground) that is coupled to an anode of a photodetector 410, is coupled to the first electrode of the transistor M1 in the second conductive path of the hybrid pixel 600. In some implementations, the reference voltage 625 is between the first reference voltage 402 and the second reference voltage 404. As shown in FIG. 6, the reference voltage 625 increases the gate voltage of the transistor M1. In some implementations, the reference voltage 625 increases the gate voltage of the transistor M1 relative to the photodetector 410 of the hybrid pixel 600.

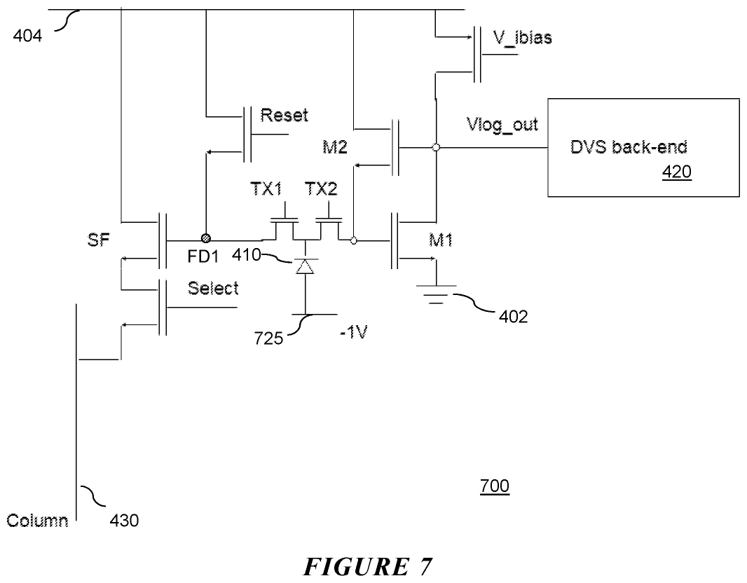

FIG. 7 is a block diagram of still yet another example pixel for an imaging sensor that is capable of detecting illumination intensity or contrast change using a shared photodetector in accordance with some implementations. As shown in FIG. 7, the photodiode 410 is connected through a first conductive readout path (e.g., 4T pixel) to an output column or the output 430 in the first mode of operation of a hybrid pixel 700 as described with respect to FIG. 4. As shown in FIG. 7, an additional reference voltage is coupled in a second conductive path of the hybrid pixel 700. As shown in FIG. 7, the first reference voltage 402 (e.g., ground) is coupled to the first electrode of the transistor M1 and a reference voltage 725 (e.g., a fixed voltage) different from the first reference voltage is coupled to the anode of the photodetector 410 in the second conductive path of the hybrid pixel 700. In some implementations, the reference voltage 725 is less than the first reference voltage 402 and the second reference voltage 404. For example, the reference voltage 725 is −1 volt (V). As shown in FIG. 7, the reference voltage 725 increases the gate voltage of the transistor M1 relative to the photodetector 410. In some implementations, the reference voltage 725 increases the gate voltage of the transistor M1 relative to the photodetector 410 in the second mode of the hybrid pixel 700.

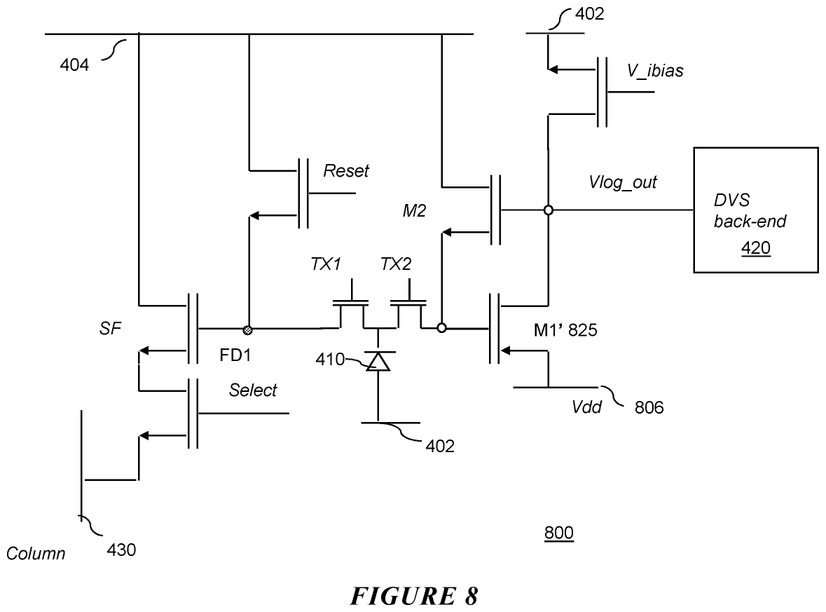

FIG. 8 is a block diagram of still yet another example pixel for an imaging sensor that is capable of detecting illumination intensity or contrast change using a single photodetector in accordance with some implementations. As shown in FIG. 8, the photodiode 410 is connected through a first conductive readout path (e.g., 4T pixel) to an output column or the output 430 in the first mode of operation of a hybrid pixel 800 as described with respect to FIG. 4. As shown in FIG. 8, a PMOS transistor M1′ 825 is coupled in a second conductive path of the hybrid pixel 800. In some implementations, the PMOS transistor M1′ 825 has the first electrode coupled to a reference voltage 806 (e.g., Vdd) different from the first reference voltage 402 in the second conductive path of the hybrid pixel 700. As shown in FIG. 8, a voltage drop (e.g., Vgs) from the first electrode to the gate of the PMOS transistor M1′ 825 varies according to the technology used to implement the hybrid pixel 800. For example, a voltage drop from the first electrode to the gate of the PMOS transistor M1′ 825 is 0.5 V or 1 V. In some implementations, the reference voltage 806 is 2.5 V or 2.0 V. In some implementations, the reference voltage 806 increases the gate voltage of the transistor M1′ 825 relative to the photodetector 410 in the second mode of the hybrid pixel 800.

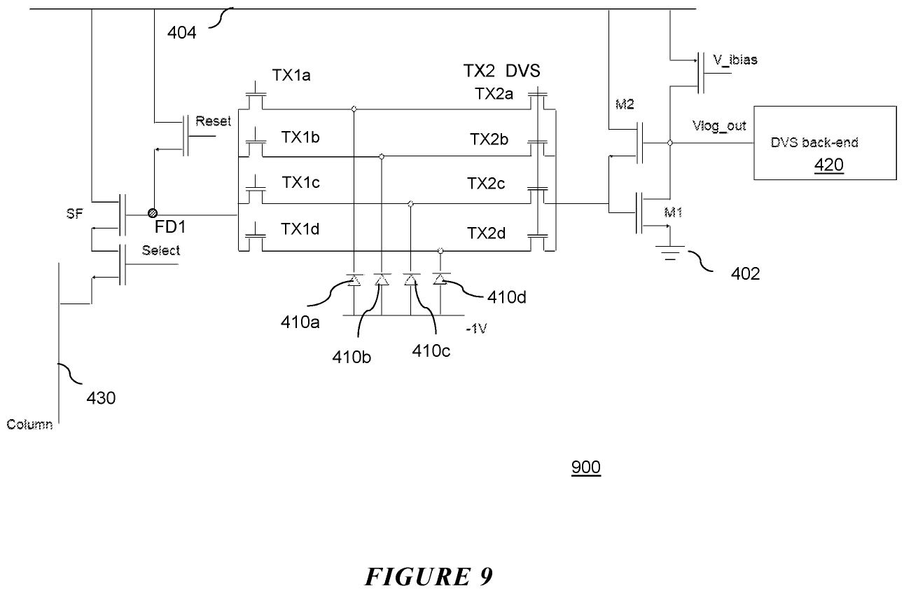

FIG. 9 is a block diagram of still yet another example pixel for an imaging sensor that is capable of detecting illumination intensity or contrast change using shared photodetectors in accordance with some implementations. As shown in FIG. 9, a plurality of photodetectors (e.g., 4 photodiodes) can be used as 4 independent intensity pixels, or binned together to perform event detection as a single contrast change pixel.

As shown in FIG. 9, photodetectors 410a-410d are respectively connected through a first conductive readout path (e.g., 4T pixel) to an output column or the output 430 in the first mode of operation of a hybrid pixel 900 as described with respect to FIG. 4. In some implementations, the photodetectors 410a-410d are respectively read out by sequentially enabling first readout transistors TX1a-TX1d (e.g., after an integration period). In some implementations, the photodetectors 410a-410d form a repeating Bayer pattern of pixels (e.g., Red, Green, Blue, Green; etc.) in an image sensor. In some implementations, the hybrid pixel 900 is considered to use a plurality of time-sequenced first output paths (e.g., 4) in the first mode.

As shown in FIG. 9, the photodetectors 410a-410d are respectively connected through a second conductive readout path to the DVS back-end 420 in the second mode of operation of a hybrid pixel 900 as described with respect to FIG. 4. In some implementations, photocurrent from the photodetectors 410a-410d is continuously output to the DVS back-end 420 in the second mode. In some implementations, the photocurrent from the photodetectors 410a-410d is continuously output to the DVS back-end 420 in the second mode by concurrently enabling a plurality of corresponding second readout transistors TX2a-TX2d. In some implementations, the plurality of second readout transistors TX2a-TX2d are concurrently enabled using a control signal TX2_DVS. In some implementations, the control signal TX2_DVS is set high (e.g., enable) in the second mode. In some implementations, the control signal TX2_DVS is set low (e.g., disable) in the first mode of the hybrid pixel 900. In some implementations, the hybrid pixel 900 is used in low light (e.g., contrast) conditions.

In some implementations, the hybrid pixel 900 includes the first readout path or the second readout path that operates as described herein with respect to FIGS. 4-6, FIG. 8, etc. Although shown with 4 photodetectors 410a-410d in FIG. 9, in some implementations the hybrid pixel 900 could use a different number of photodetectors (e.g., 2, 3, 8, 12, etc.). In some implementations, the hybrid pixel 900 uses a first higher resolution in the first mode and a second lower resolution in the second mode. As shown in FIG. 9, the hybrid pixel 900 has a resolution in the first mode that is 4 times higher than the resolution in the second mode.

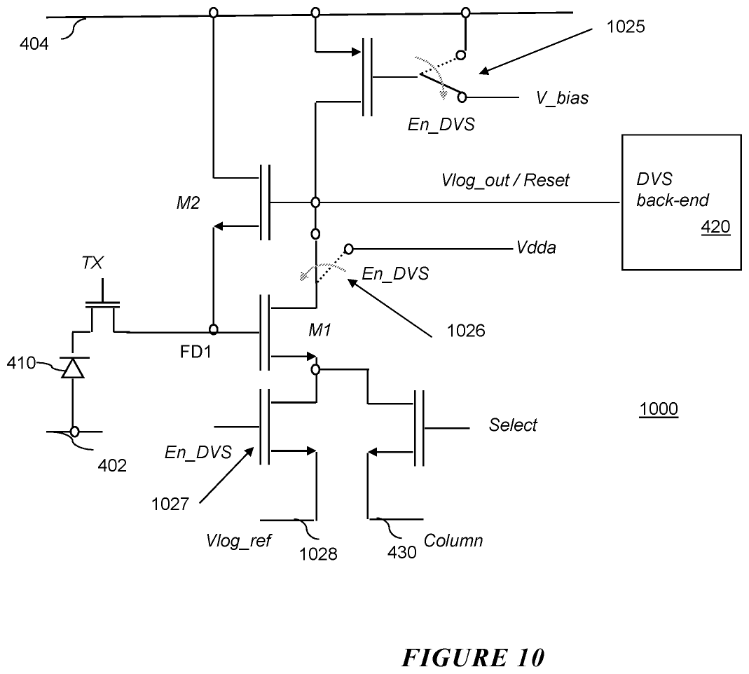

FIG. 10 is a block diagram of still yet another example pixel for an imaging sensor that is capable of detecting illumination intensity or contrast change using a single photodetector in accordance with some implementations. As shown in FIG. 10, transistors in a hybrid pixel 1000 can be shared between a first mode of operation (e.g., a frame-based camera mode, illumination intensity detection operations, 4T pixel) and a second mode of operation (e.g., an event camera mode, contrast change detection operations). In some implementations, contrast change detection and illumination intensity detection can be time multiplexed. In some implementations, photocurrent is integrated on (e.g., at a node such as FD1) during illumination intensity detection or frame-based camera mode. In some implementations, photocurrent flows into input device (e.g., transistor M2) in contrast change detection or event camera mode. In some implementations, a determination to use the event camera mode or the frame-based camera mode is made at a global or system level (e.g., the imaging sensor). In some implementations, a illumination intensity detection mode is triggered by contrast change detection event in the same pixel.

As shown in FIG. 10, the first conductive readout path and the second conductive readout path for the photodetector 410 in the hybrid pixel 1000 are not separate paths. In some implementations, at least some circuit devices (e.g., transistors, reference voltages, control signals) are shared between the first mode and the second mode of the hybrid pixel 1000. In some implementations, the hybrid pixel 1000 implements the first conductive path when a control signal (e.g., enable DVS) is low or off and implements the second conductive path when the control signal (e.g., enable DVS) is high or on.

As shown in FIG. 10, when a control signal En_DVS is enabled, a switch 1025 connects a gate of the bias transistor to a bias voltage V_bias (e.g., V_ibias), and a switch 1026 connects the second electrode of the transistor M1 to the input terminal of the DVS back-end 420. Further, when the control signal En_DVS is enabled, a transistor 1027 is enabled and connects the first electrode of the transistor M1 to a reference voltage 1028 (e.g., Vdd, V_bias_low), which is set to ensure the gate voltage of the transistor M1 is higher than the pinning voltage of the photodetector 410. In some implementations, the anode of the photodetector 410 is connected to −1 V and the reference voltage 1028 is the ground voltage. Thus, as shown in FIG. 10, when the control signal En_DVS is enabled and the TX transistor is enabled, the transistors M1 and M2 form a logarithmic amplifier connected between the photodetector 410 and the input to the DVS back-end 420. Thus, as shown in FIG. 10, when the control signal En_DVS is enabled, the hybrid pixel 1000 operates in the second mode.

As shown in FIG. 10, when the control signal En_DVS is disabled (e.g., low) the transistor M1 becomes the source follower transistor and the transistor M2 becomes the reset transistor in 4T pixel operations to form the first conductive readout path between the photodetector 410 and the output 430 (e.g., column bus). In some implementations, when the control signal En_DVS is disabled, the switch 1025 connects the gate of the bias transistor to the second reference voltage 404, the switch 1026 connects the second electrode of the transistor M1 to the reference voltage 404 (e.g., through the bias transistor with its gate connected by the switch 1025 to the second reference voltage 404), and the transistor 1027 is disabled so that the first electrode of the transistor M1 is connected to the second electrode of the select transistor. Thus, as shown in FIG. 10, when the control signal En_DVS is disabled, the hybrid pixel 1000 operates in the first mode, and the TX transistor receives a control signal as described in FIG. 13.

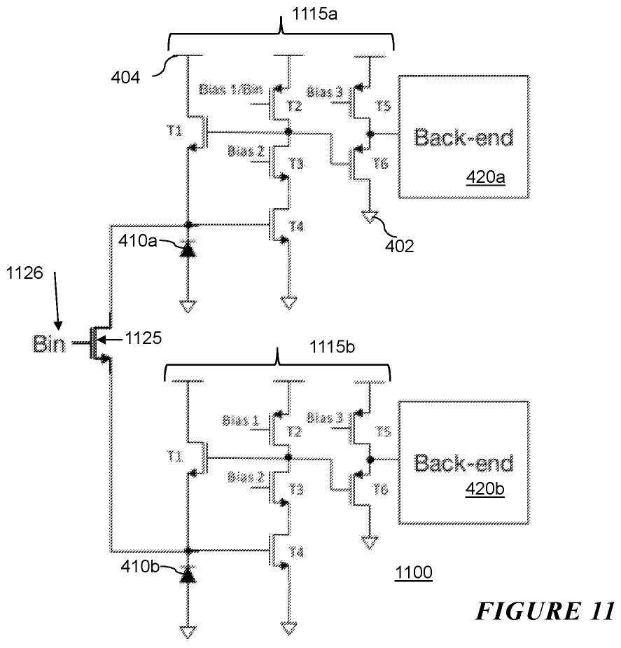

FIG. 11 is a block diagram of another example of an imaging sensor including binning during contrast change detection using a photodetector in accordance with some implementations. As shown in FIG. 11, contrast change detection binning can be performed by summing photocurrent of 2 or more photosensors into one amplifier. In some implementations, bias lines of the other amplifiers should be turned off (e.g., railed).

As shown in FIG. 11, an image sensor for contrast change detection includes 2 photodetectors 410a, 410b that are each connected through a DVS front-end 1115a, 1115b to a corresponding DVS back-end 420a, 420b. In some implementations, a binning circuit is configured to connect both of the photodetectors 410a, 410b through a single DVS front-end 1115b to a single DVS back-end 420b when the binning circuit is enabled. In some implementations, the DVS front-end 1115a and the DVS back-end 420a that are not being used during binning operations are disabled or isolated.

As shown in FIG. 11, the DVS front-end 1115a, 1115b include 6 transistors, and the binning circuit includes a bin transistor 1125 and a bin control signal (Bin). In some implementations, the DVS front-end 1115a, 1115b generates a logarithmic relationship between the photocurrent from the photodetector 410a, 410b and the input signal to the corresponding DVS back-end 420a, 420b when individual photodetector readout occurs (e.g., when the Bin control signal 1126 is disabled or low). In some implementations during binning operations, the Bin control signal 1126 is enabled and the photocurrent from both photodetectors 410a, 410b are combined through the DVS front-end 1115b to the DVS back-end 420b. In some implementations during binning operations, the Bin control signal 1126 is enabled and the DVS front-end 1115a and the DVS back-end 420a that are not being used during binning operations are disabled or isolated. As shown in FIG. 11, the transistor T2 in the DVS front-end 1115a is disabled by the enabled Bin control signal 1126. In some implementations, the resolution of the image sensor in FIG. 11 during binning operations will be less than the resolution of the image sensor during individual photodetector readout.

In some implementations, binning operations described with respect to FIG. 11 are enabled in low contrast conditions (e.g., low light). In some implementations, binning operations described with respect to FIG. 11 are enabled in low contrast conditions where photocurrent generated by a single photodetector is insufficient to generate events at the DVD back-end, but photocurrent from a plurality of photodetectors (e.g., 2, 4, 10) is enough to generate events at the DVS back-end.

Although two photodetectors are shown in FIG. 11, the application is not intended to be so limited. In some implementations, an image sensor for contrast change detection includes a plurality of N photodetectors that are each connected through N DVS front-ends to a corresponding one of N DVS back-ends, where N is a positive integer greater than 1, and a binning circuit is configured to connect the N photodetectors through a single DVS front-end to a single one of the N DVS back-ends. In some implementations, the binning circuit is also configured to disable the un-used N−1 DVS front-ends and to disable the un-used N−1 DVS back-ends. In some implementations, the transistors T4 and T1 correspond to the transistors M1 and M2 shown in FIGS. 4-10.

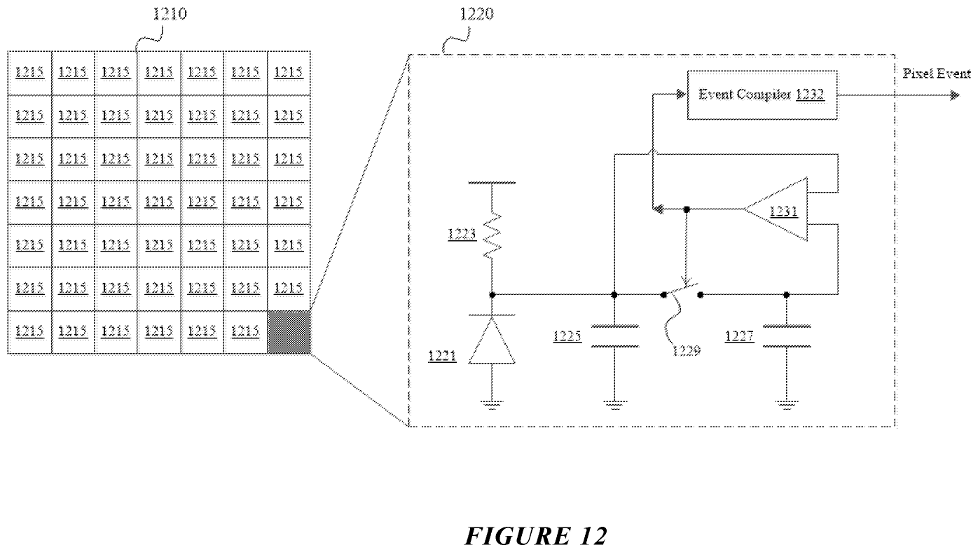

FIG. 12 is a block diagram of pixel sensors for an example event camera or dynamic vision sensor (DVS) and an example circuit diagram of a pixel sensor, in accordance with some implementations. As illustrated by FIG. 12, pixel sensors 1215 may disposed on an event camera at known locations relative to an electronic device (e.g., the electronic device 120 of FIG. 1) by arranging the pixel sensors 1215 in a 2D matrix 1210 of rows and columns. In the example of FIG. 12, each of the pixel sensors 1215 is associated with an address identifier defined by one row value and one column value.

FIG. 12 also shows an example circuit diagram of a circuit 1220 that is suitable for implementing a pixel sensor 1215. In the example of FIG. 12, circuit 1220 includes photodiode 1221, resistor 1223, capacitor 1225, capacitor 1227, switch 1229, comparator 1231, and event compiler 1232. In operation, a voltage develops across photodiode 1221 that is proportional to an intensity of light incident on the pixel sensor. Capacitor 1225 is in parallel with photodiode 1221, and consequently a voltage across capacitor 1225 is the same as the voltage across photodiode 1221.

In circuit 1220, switch 1229 intervenes between capacitor 1225 and capacitor 1227. Therefore, when switch 1229 is in a closed position, a voltage across capacitor 1227 is the same as the voltage across capacitor 1225 and photodiode 1221. When switch 1229 is in an open position, a voltage across capacitor 1227 is fixed at a previous voltage across capacitor 1227 when switch 1229 was last in a closed position. Comparator 1231 receives and compares the voltages across capacitor 1225 and capacitor 1227 on an input side. If a difference between the voltage across capacitor 1225 and the voltage across capacitor 1227 exceeds a threshold amount (“a comparator threshold”), an electrical response (e.g., a voltage) indicative of the intensity of light incident on the pixel sensor is present on an output side of comparator 1231. Otherwise, no electrical response is present on the output side of comparator 1231.

When an electrical response is present on an output side of comparator 1231, switch 1229 transitions to a closed position and event compiler 1232 receives the electrical response. Upon receiving an electrical response, event compiler 1232 generates a pixel event and populates the pixel event with information indicative of the electrical response (e.g., a value or polarity of the electrical response). In one implementation, event compiler 1232 also populates the pixel event with one or more of: timestamp information corresponding to a point in time at which the pixel event was generated and an address identifier corresponding to the particular pixel sensor that generated the pixel event.

An event camera generally includes a plurality of pixel sensors like pixel sensor 1215 that each output a pixel event in response to detecting changes in light intensity that exceed a comparative threshold. When aggregated, the pixel events output by the plurality of pixel sensor form a stream of pixel events that are output by the event camera. In some implementations, light intensity data obtained from the stream of pixel events output by an event camera is used to implement various applications. When the event camera is disposed on one device among a first electronic device and a second electronic device, at least a portion of the changes in light intensity correspond to light emitted by a one or more of optical sources disposed on the other device among the first electronic device and the second electronic device.

FIG. 13 is a diagram of an example arrangement of a 4 transistor (4T) pixel. In some implementations, an image sensor is a 2D array of photo-sensitive pixels that, when the data from them is correctly acquired and processed, produces a frame or an image. A photodiode lies in the photo-sensitive region of the pixel and collects charge proportional to the number of photons hitting its surface. Each row of pixels is connected to a select transistor that determines which row of pixels has been selected for read out at any one time. Once a row select transistor has been engaged, the pixel is reset via the reset transistor (which acts as a switch) and the charge accumulated by the photodiode during the light detection, or integration, period is buffered by a source follower transistor before being transferred to the column bus. In normal 4T operation, an integration period is completed, followed by the resetting of the separate readout node (e.g., the floating diffusion node). This reset value is then sampled before the transfer gate is opened in order to sample the signal value and empty the diode (e.g., correlated double sampling (CDS). In some implementations, CDS operates to reduce or eliminate both fixed pattern noise and kTC noise because the noise from the floating diffusion node capacitance is read in both the signal and reset value, thus it is thus reduced or eliminated when the two signals are subtracted. In some implementations, a 4T pixel is a variation of the conventional 3T pixel.

Numerous specific details are set forth herein to provide a thorough understanding of the subject matter. However, those skilled in the art will understand that the subject matter may be practiced without these specific details. In other instances, methods apparatuses, or systems that would be known by one of ordinary skill have not been described in detail so as not to obscure subject matter.

Unless specifically stated otherwise, it is appreciated that throughout this specification discussions utilizing the terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provides a result conditioned on one or more inputs. Suitable computing devices include multipurpose microprocessor-based computer systems accessing stored software that programs or configures the computing system from a general purpose computing apparatus to a specialized computing apparatus implementing one or more implementations of the present subject matter. Any suitable programming, scripting, or other type of language or combinations of languages may be used to implement the teachings contained herein in software to be used in programming or configuring a computing device.

Implementations of the methods disclosed herein may be performed in the operation of such computing devices. The order of the blocks presented in the examples above can be varied for example, blocks can be re-ordered, combined, and/or broken into sub-blocks. Certain blocks or processes can be performed in parallel.

In accordance with some implementations, a device includes one or more processors, a non-transitory memory, and one or more programs; the one or more programs are stored in the non-transitory memory and configured to be executed by the one or more processors and the one or more programs include instructions for performing or causing performance of any of the methods described herein. In accordance with some implementations, a non-transitory computer readable storage medium has stored therein instructions, which, when executed by one or more processors of a device, cause the device to perform or cause performance of any of the methods described herein. In accordance with some implementations, a device includes: one or more processors, a non-transitory memory, and means for performing or causing performance of any of the methods described herein.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or value beyond those recited. Headings, lists, and numbering included herein are for ease of explanation only and are not meant to be limiting.

It will also be understood that, although the terms “first,” “second,” etc. may be used herein to describe various elements, these elements should not be limited by these terms. These terms are only used to distinguish one element from another. For example, a first node could be termed a second node, and, similarly, a second node could be termed a first node, which changing the meaning of the description, so long as all occurrences of the “first node” are renamed consistently and all occurrences of the “second node” are renamed consistently. The first node and the second node are both nodes, but they are not the same node.

The terminology used herein is for the purpose of describing particular implementations only and is not intended to be limiting. As used in the description of the implementations, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description and summary of the invention are to be understood as being in every respect illustrative and exemplary, but not restrictive, and the scope of the invention disclosed herein is not to be determined only from the detailed description of illustrative implementations but according to the full breadth permitted by patent laws. It is to be understood that the implementations shown and described herein are only illustrative of the principles of the present invention and that various modification may be implemented by those skilled in the art without departing from the scope and spirit of the invention.

1. A system comprising:
a matrix arrangement of a plurality of addressable pixels, each of the pixels comprising:
a photodetector;
a first conductive readout path selectively coupled to the photodetector, the first conductive readout path configured to detect a change in light intensity exceeding a threshold detected by the photodetector; and
a second conductive readout path selectively coupled to the photodetector, the second conductive readout path configured to transfer a charge corresponding to accumulated light intensity detected by the photodetector.

2. The system of claim 1, wherein the first conductive readout path comprises:
a first transistor having a first terminal coupled to a second terminal of the photodetector, a third terminal coupled to a first mode signal to transfer photocurrent from the photodetector in a first mode;
a second transistor having a second terminal coupled to a second terminal of the first transistor, a first terminal coupled to a first reference voltage, and a second terminal coupled to an event camera data output circuit;
a third transistor having a first terminal coupled to the second terminal of the first transistor, a second terminal coupled to a second reference voltage, and a third terminal coupled to the event camera data output circuit; and
a fourth transistor having a first terminal coupled to the second reference voltage, a second terminal coupled to the event camera data output circuit, and a third terminal coupled to a bias signal.

3. The system of claim 1, wherein a first terminal of the photodetector is coupled to a ground voltage.

4. The system of claim 1, further comprising:
a level shifting circuit coupled between the first terminal of the second transistor and the first reference voltage.

5. The system of claim 4, wherein the level shifting circuit comprises a transistor having a first terminal coupled to the first reference voltage, and a second terminal coupled to the first terminal of the second transistor, and a third terminal coupled to the second terminal.

6. The system of claim 1, wherein the first reference voltage is a ground voltage.

7. The system of claim 1, wherein the first reference voltage is a low bias voltage higher than a ground voltage and the first terminal of the photodetector is coupled to a negative voltage.

8. The system of claim 1, wherein the second transistor is a positively doped transistor and the first reference voltage is positive voltage less than the second reference voltage.

9. The system of claim 1, wherein the second conductive readout path comprises:
a fifth transistor having a first terminal coupled to the second terminal of the photodetector, a third terminal coupled to a second mode signal to transfer photo-generated charges from the photodetector in a second mode;
a sixth transistor having a third terminal coupled to a second terminal of the fifth transistor, and a second terminal coupled to the second reference voltage;
a seventh transistor having a second terminal coupled to a first terminal of the sixth transistor, a third terminal coupled to a row select signal, and a second terminal coupled to a output terminal; and
an eighth transistor having a first terminal coupled to a third terminal of the sixth transistor, a third terminal coupled to a reset signal, and a second terminal coupled to the second reference voltage.

10. The system of claim 9, wherein a floating diffusion node coupled between the first terminal of the eighth transistor, the second terminal of the fifth transistor, and the third terminal of the sixth transistor.

11. The system of claim 1, wherein the first conductive readout path, comprises:
a first transistor having a first terminal coupled to a second terminal of the photodetector, a third terminal selectively coupled to a first mode signal to transfer photocurrent from the photodetector in a first mode;
a second transistor having a third terminal coupled to a second terminal of the first transistor, a first terminal selectively coupled to a first reference voltage by the first mode signal, and a second terminal coupled to an event camera data output circuit by the first mode signal;
a third transistor having a first terminal coupled to the second terminal of the first transistor, a second terminal coupled to a second reference voltage, and a third terminal coupled to the event camera data output circuit by the first mode signal; and
a fourth transistor having a first terminal coupled to the second reference voltage, a second terminal coupled to the event camera data output circuit, and a third terminal coupled to a bias signal by the first mode signal.

12. The system of claim 11, wherein the second conductive readout path comprises:
the first transistor having the third terminal selectively coupled to a second mode signal to transfer photo-generated charges from the photodetector in a second mode;
the second transistor having the second terminal selectively coupled the second reference voltage by the second mode signal;
a third transistor having the third terminal selectively coupled to a reset signal by the second mode signal; and
a fifth transistor having a first terminal coupled to an output bus, a second terminal selectively coupled to the second terminal of the second transistor by the second mode signal, and a third terminal coupled to a select signal.

13. The system of claim 1, wherein each of the pixels comprises a plurality of photodetectors, wherein the plurality of photoconductors are concurrently coupled to the first conductive readout path, and wherein the plurality of photoconductors individually and sequentially coupled to the second conductive readout path.

14. The system of claim 1, wherein a first terminal is a source terminal, the second terminal is a drain terminal, and the third terminal is a gate terminal.

15. The system of claim 1, wherein event camera data corresponds to pixel events triggered based on changes in light intensity at pixel sensors exceeding a comparator threshold.

16. An event image sensor comprising:
a matrix arrangement of a plurality of pixels, comprising:
a plurality of photodetectors configured to receive light from a physical environment, each photodetector corresponding to one of the pixels;
a plurality of readout circuits, each of the readout circuits configured to receive pixel data to detect a change in light intensity exceeding a threshold detected by a photodetector; and
a binning circuit configured to operate in a first mode and a second mode, the binning circuit is configured to electrically connect a single photodetector of the plurality of photodetectors to a single readout circuit of the plurality of readout circuits in the first mode, and the binning circuit is configured to electrically connect more than one photodetector of the plurality of photodetectors to a single readout circuit of the plurality of readout circuits in the second mode.

17. The event image sensor of claim 16, wherein the binning circuit is configured to electrically connect the plurality of photodetectors to the single readout circuit in the second mode.
